(19) United States
(12) Patent Application Publication
(10) Pub. No.: US 2025/0126736 A1
(43) Pub. Date: Apr. 17, 2025

(54) SERVER APPARATUS AND CONTAINING MECHANISM THEREOF

(71) Applicant: WISTRON CORPORATION, New Taipei City (TW)

(72) Inventor: Weihao CHEN, New Taipei City (TW)

(73) Assignee: WISTRON CORPORATION, New Taipei City (TW)

(21) Appl. No.: 18/592,864

(22) Filed: Mar. 1, 2024

(30) Foreign Application Priority Data
Oct. 13, 2023 (TW) 112139199

(51) Int. Cl. H05K 7/14

(52) U.S. Cl. CPC H05K 7/1489; H05K 7/1405; H05K 7/1487

(57) ABSTRACT

A server apparatus includes a server casing, a main body disposed in the server casing, first and second electronic components, and a containing mechanism. The containing mechanism includes a containing casing, first and second support members, and a first bridge member. The containing casing is located in the server casing and has a first side plate. The first bridge member is pivoted to the first and second support members to make the first support member movable relative to the second support member. The first and second electronic components are mounted on the first and second support members respectively and connected to the main body. A first fixing part of the first support member is detachably fixed to the first side plate for mounting the first and second electronic components within the containing casing.

### CROSS-REFERENCE TO RELATED APPLICATION

This application claims the priority and benefit of Taiwan Patent Application No. 112139199, filed on Oct. 13, 2023, the disclosure of which is hereby incorporated in its entirety by reference herein.

### Technical Field

The present disclosure relates to a server apparatus and a containing mechanism thereof, and more specifically, to a server apparatus disposing a first support member and a second support member linked to each other via a first bridge member in the containing casing for mounting a first electronic component and a second electronic component in the containing casing and a containing mechanism thereof.

### BACKGROUND

### Description of the Prior Art

With the development of technology, there is an increasing demand for cloud computing devices, leading to a significant rise in server requirements. Simultaneously, the expectations for the computational performance of a server are gradually increased. Thus, expansion electronic components, such as network cards complying with the OCP (Open Compute Project) 3.0 specification or 2.5-inch hard drive devices, are usually mounted therein for improving the overall computing capability of the server. In practical applications, a tray mechanism is commonly utilized to securely mount the expansion electronic components within a server casing.

However, the current configuration of mounting the expansion electronic components on the tray mechanism adopts a design where the expansion electronic components are horizontally adjacent to each other. As such, this design may fully occupy the horizontal configuration space of the server casing, preventing the possibility of adding extra input-output (I/O) ports (e.g., USB (Universal Serial Bus) ports) on the server casing. Moreover, since different types of expansion electronic components have different mounting sizes, causing many constraints to the server apparatus in the expansion configuration.

### SUMMARY

The present disclosure provides a server apparatus including a server casing, a main body, a containing mechanism, a first electronic component, and a second electronic component. The main body is disposed in the server casing. The containing mechanism includes a containing casing, a first support member, a second support member, and at least one first bridge member. The containing casing is located in the server casing and has a first side plate. The first support member has a first fixing part, a first holding portion, and a first connection portion extending from the first holding portion. The first fixing part is disposed on the first connection portion. The second support member has a second holding portion and a second connection portion extending from the second holding portion. The at least one first bridge member is pivoted to the first connection portion and the second connection portion respectively. The first support member is movable relative to the second support member via the at least one first bridge member. The first electronic component is located on the first holding portion and connected to the main body. The second electronic component is located on the second holding portion and connected to the main body. The first fixing part is detachably fixed to the first side plate.

The present disclosure further provides a containing mechanism suitable for a server casing. The containing mechanism includes a containing casing, a first support member, a second support member, and at least one first bridge member. The containing casing is located in the server casing and has a first side plate. The first support member has a first fixing part, a first holding portion, and a first connection portion extending from the first holding portion. The first fixing part is disposed on the first connection portion. The second support member has a second holding portion and a second connection portion extending from the second holding portion. The at least one first bridge member is pivoted to the first connection portion and the second connection portion respectively to make the first support member movable relative to the second support member. A first electronic component and a second electronic component are located on the first holding portion and the second holding portion respectively, and the first fixing part is detachably fixed to the first side plate.

These and other objectives of the present disclosure will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an exploded diagram of a server apparatus according to an embodiment of the present disclosure.

FIG. 2 is a partially enlarged diagram of a first support member, a linkage member, a second support member, a first bridge member, a third support member, and a second bridge member linked to each other being mounted on a first side plate.

FIG. 3 is a partially enlarged diagram of a rail member in FIG. 1 fixed to the first support member.

FIG. 4 is a partially exploded diagram of the rail member, another first support member, another linkage member, another second support member, another first bridge member, another third support member, and another second bridge member in FIG. 1 from another viewing angle.

FIG. 5 is an assembly diagram of a first fixing part in FIG. 2 rotating to be engaged with the first side plate.

FIG. 6 is an assembly diagram of a containing casing with a first electronic component, a second electronic component, and a third electronic component being disposed through an opening of a server casing.

FIG. 7 is an assembly diagram of a first electronic component, a second electronic component, the third electronic component and a containing mechanism according to another embodiment of the present disclosure.

FIG. 8 is an enlarged diagram of the first support member being connected to the second support member via a first bridge member according to another embodiment of the present disclosure.

FIG. 9 is an enlarged diagram of the first support member, the second support member, and the first bridge member in FIG. 8 from another viewing angle.

FIG. 10 is an enlarged diagram of the first support member in FIG. 9 being aligned with the second support member via the first bridge member.

### DETAILED DESCRIPTION

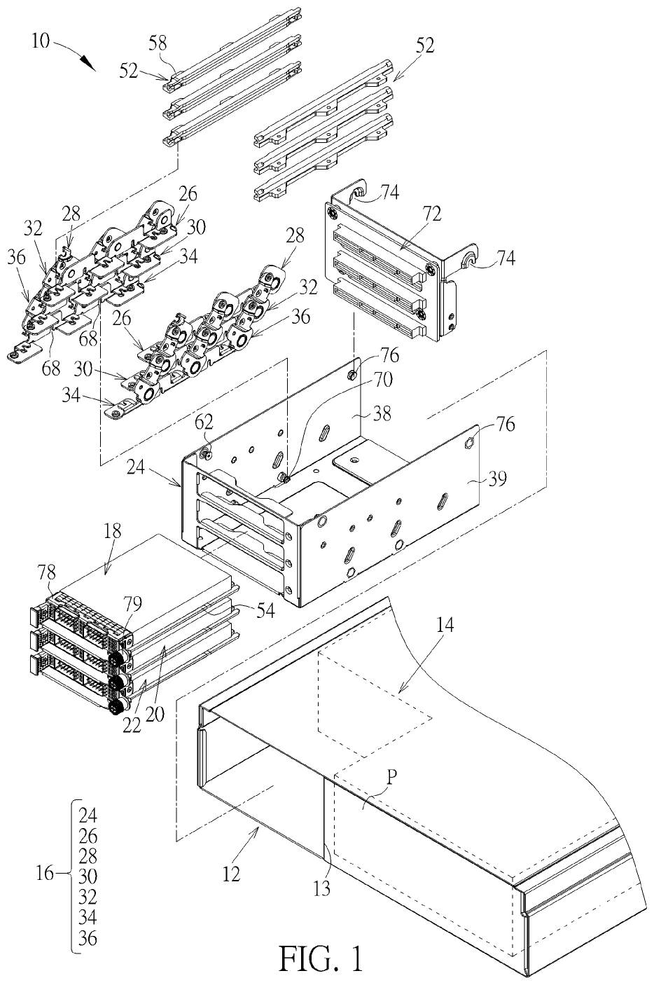

Please refer to FIG. 1, which is an exploded diagram of a server apparatus 10 according to an embodiment of the present disclosure. For clearly showing the structural relationship of the server apparatus 10, only a partial structure of a server casing 12 is shown in FIG. 1, and a main body 14 is represented by dashed lines in FIG. 1. As shown in FIG. 1, the server apparatus 10 includes the server casing 12, the main body 14, a containing mechanism 16, a first electronic component 18, a second electronic component 20, and a third electronic component 22. The first electronic component 18, the second electronic component 20, and the third electronic component 22 are preferably common expansion electronic devices used in a server equipment, such as network cards complying with the OCP 3.0 specification or 2.5-inch hard drive devices. A portion of a front end P of the server casing 12 is preferably formed with an opening 13 (but not limited thereto). The main body 14 is disposed in the server casing 12 and could include main components used in a server equipment, such as heat dissipation modules, motherboard modules, power modules, etc., and the related description is commonly seen in the prior art and omitted herein.

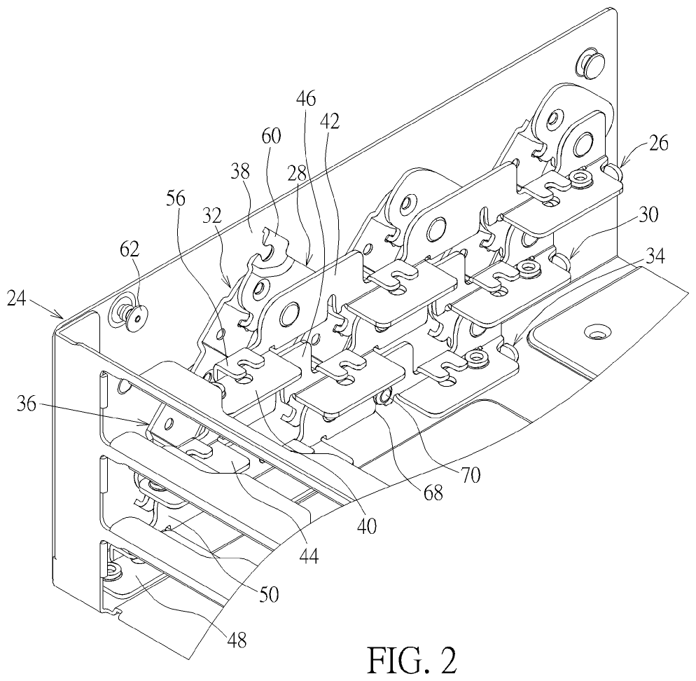

More detailed description for the mechanical design of the containing mechanism 16 is provided as follows in the configuration that the first electronic component 18, the second electronic component 20, and the third electronic component 22 are network cards complying with the OCP 3.0 specification (but not limited thereto). As shown in FIG. 1 and FIG. 2, the containing mechanism 16 includes a containing casing 24 (e.g., a server tray, but not limited thereto), a first support member 26, a second support member 30, at least one first bridge member 32, a third support member 34, and at least one second bridge member 36. The first support member 26 could include at least one linkage member 28, wherein the quantities of the linkage member 28, the first bridge member 32, and the second bridge member 36 are shown as three in FIG. 1 respectively (but not limited thereto, meaning that the actual configuration depends on the supporting needs of the containing mechanism 16). The containing casing 24 is preferably disposed through the opening 13 and has a first side plate 38 and a second side plate 39 opposite to each other. The containing casing 24 is used to support the first electronic component 18, the second electronic component 20, and the third electronic component 22 to be mounted in the opening 13 of the server casing 12. In practical applications, the support design of the containing mechanism 16 could be preferably applied to two side plates of the containing casing 24 for securely mounting the first electronic component 18, the second electronic component 20, and the third electronic component 22 in the server casing 12 (but not limited thereto, meaning that the support design could be only applied to one side plate of the containing casing 24 for simplifying the containing mechanical design of the server apparatus 10). For simplicity, the following description focuses on the design of fixing the first side plate 38 of the containing casing 24 to the first support member 26, the linkage member 28, the second support member 30, the first bridge member 32, the third support member 34, and the second bridge member 36. As for the design of fixing another first support member 26, another linkage member 28, another second support member 30, another first bridge member 32, another third support member 34, and another second bridge member 36 to the second side plate 39, the related description could be reasoned by analogy according to the following description and omitted herein.

As shown in FIG. 1 and FIG. 2, the first support member 26 has a first support portion 40 and a first connection portion 42 extending upwardly from the first support portion 40. The second support member 30 has a second support portion 44 and a second connection portion 46 extending upwardly from the second support portion 44. The third support member 34 has a third support portion 48 and a third connection portion 50 extending upwardly from the third support portion 48. The linkage member 28 is pivotally connected to the first connection portion 42, and the first bridge member 32 is pivotally connected to the second connection portion 46 and connected to the linkage member 28 to position the first support member 26 above the second support member 30. The second bridge member 36 is pivotally connected to the third connection portion 50 and connected to the first bridge member 32 to position the third support member 34 below the second support member 30. In such a manner, via the pivotal connection between the linkage member 28 and the first connection portion 42, the pivotal connection between the first bridge member 32 and the second connection portion 46, and the pivotal connection between the second bridge member 36 and the third connection portion 50, the first support member 26 and the third support member 34 can be offset relative to the second support member 30 or aligned with the second support member 30 for the subsequent electronic component mounting process.

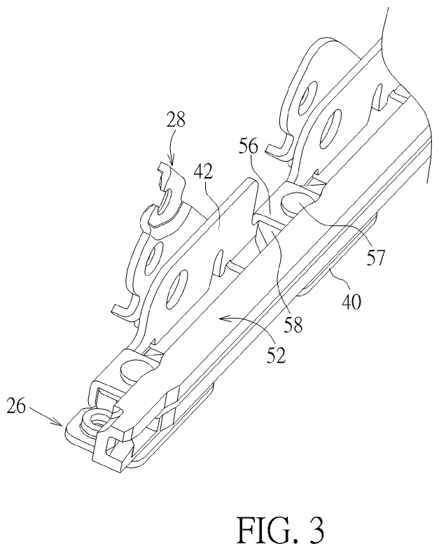

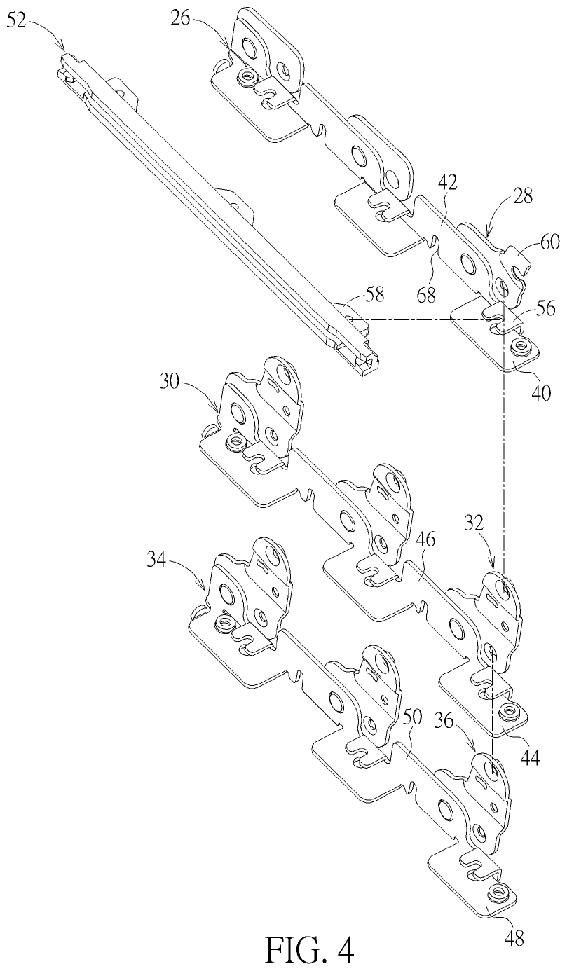

To be more specific, in this embodiment, the present disclosure preferably adopts a rail assembly design (but not limited thereto, meaning that the present disclosure could adopt other assembly designs, such as mounting the first electronic component 18 on the first support member 26 in a structural engagement manner). For example, please refer to FIGS. 1-4. FIG. 3 is a partially enlarged diagram of a rail member 52 in FIG. 1 fixed to the first support member 26. FIG. 4 is a partially exploded diagram of the rail member 52, the another first support member 26, the another linkage member 28, the another second support member 30, the another first bridge member 32, the another third support member 34, and the another second bridge member 36 in FIG. 1 from another viewing angle. As shown in FIGS. 1-4, the containing mechanism 16 could further include the rail member 52, and the first electronic component 18 has a side piece 54 corresponding to the rail member 52. The first connection portion 42 is bent toward the first support portion 40 to form at least one clamping piece 56 (three shown in FIG. 2, but not limited thereto), and the rail member 52 has a protrusion 58 corresponding to the clamping piece 56. The rail design of the rail member 52 could meet the size specification of a side piece of a network card complying with the OCP 3.0 specification, allowing the network card to be slidably inserted thereto. Accordingly, the protrusion 58 can be clamped between the clamping piece 56 and the first support portion 40 (e.g., utilizing a screw 57 in FIG. 3 to pass through the clamping piece 56 and the protrusion 58 for locking the protrusion 58 onto the first support portion 40, but not limited thereto). This allows the first electronic component 18 to be mounted on the first support portion 40 via slidable insertion of the side piece 54 along the rail member 52 or pulled out from the containing mechanism 16 along the rail member 52. As for the rail designs of the second electronic component 20 and the third electronic component 22, which are respectively mounted on the second support member 30 and the third support member 34 through the rail members 52, the related description could be reasoned by analogy according to the aforesaid embodiments and omitted herein. To be noted, via the design in which the first support member 26 and the third support member 34 can move transversely to the offset position respectively relative to the second support member 30 (as shown in FIG. 2), the mounting positions of the rail members 52 on the first support portion 40, the second support portion 44, and the third support portion 48 for fixing the first electronic component 18, the second electronic component 20, and the third electronic component 22 respectively can be misaligned with each other to avoid the structural blocking problem. In such a manner, a user can complete the assembly operation of the rail member 52 quickly.

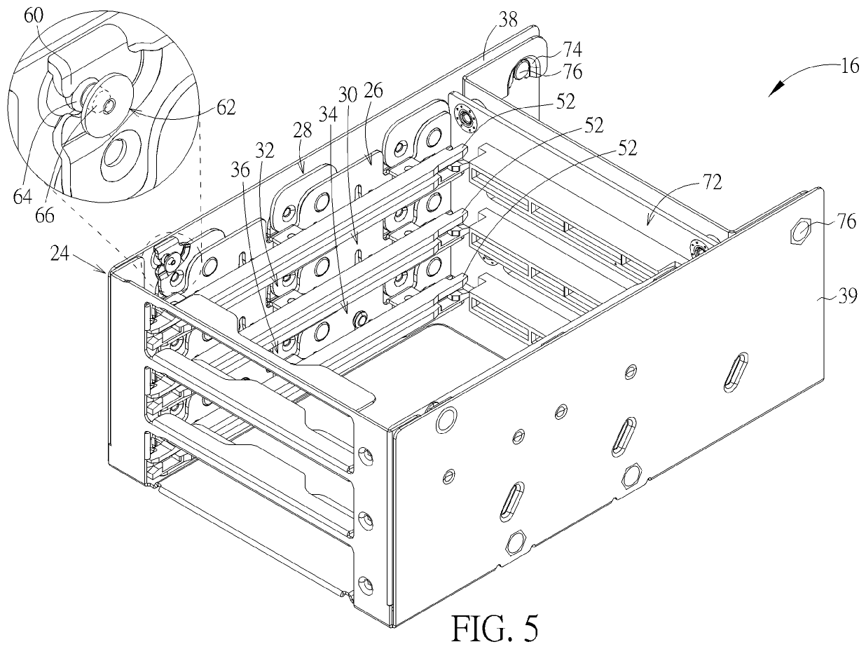

Please refer to FIGS. 1, 2, and 5 for the detachable fixing design of the first support member 26. FIG. 5 is an assembly diagram of the first fixing part 60 in FIG. 2 rotating to be engaged with the first side plate 38. As shown in FIGS. 1, 2, and 5, the first support member 26 could further include a first fixing part 60. The first fixing part 60 could be integrally formed on the linkage member 28 (for example, as shown in FIG. 2, the first fixing structure 60 could be integrally formed on the linkage member 28 located on the left side of FIG. 2). The first side plate 38 could have a second fixing part 62 corresponding to the first fixing part 60. In such a manner, when the first support member 26 moves forward to the stacking position as shown in FIG. 5 relative to the second support member 30, the first fixing part 60 is engaged with the second fixing part 62, so as to make the linkage member 28 detachably fixed to the first side plate 38. To be more specific, in this embodiment, the present disclosure preferably adopts a spring-loaded plunger design to achieve the toolless fixing effect (but not limited thereto, meaning that the present disclosure could adopt other detachable fixing designs, such as a screw-locking design). For example, the first fixing part 60 could be an engaging hook, and the second fixing part 62 could be a spring-loaded plunger. The spring-loaded plunger could have a first column portion 64 and a second column portion 66, wherein a radius of the first column portion 64 is greater than a radius of the second column portion 66. As for the related description for pressing the spring-loaded plunger to switch to the first column portion 64 or the second column portion 66, it is commonly seen in the prior art and omitted herein. Via the aforesaid design, when the spring-loaded plunger is not pressed to make the first column portion 64 with a larger radius aligned with the engaging hook, the engaging hook is securely engaged with the first column portion 64 (as shown in FIG. 5), so as to detachably fix the linkage member 28 to the first side plate 38. On the other hand, when the spring-loaded plunger is pressed to make the second column portion 66 with a smaller radius aligned with the engaging hook, the engaging hook is no longer engaged with the spring-loaded plunger. As such, the engaging hook can rotate upward relative to the first connection portion 42 to be disengaged from the spring-loaded plunger, thereby completing the disassembly operation of the linkage member 28.

In practical applications, for mounting the first support member 26, the second support member 30, and the third support member 34 connected to each other within the containing casing 24 more securely and enhancing the assembly convenience of the containing mechanism 16, the present disclosure could further adopt a positioning pin design (but not limited thereto, meaning that the present disclosure could adopt other positioning designs, such as a convex-concave positioning design). For example, as shown in FIG. 1, the third connection portion 50 could have at least one positioning groove 68 (two shown in FIG. 1, but not limited thereto), and the first side plate 38 has a positioning pin 70 corresponding to the positioning groove 68. Accordingly, the positioning groove 68 could be engaged with the positioning pin 70 for positioning the third support member 34 on the first side plate 38, so as to assist the user in quickly and accurately completing the assembly operation of mounting the first support member 26, the second support member 30, and the third support member 34 within the containing casing 24.

In addition, the present disclosure could preferably adopt a circuit board design (but not limited thereto, meaning that the present disclosure could adopt other electrical connection designs, such as a cable connection design). For example, as shown in FIG. 1 and FIG. 5, the containing mechanism 16 could include a circuit board 72 disposed upright in the containing casing 24 (e.g., by two positioning grooves 74 as shown in FIG. 1 being engaged with two positioning pins 76 on the containing casing 24, but not limited thereto). The circuit board 72 is electrically connected to the main body 14. In such a manner, when the first electronic component 18, the second electronic component 20, and the third electronic component 22 are mounted on the first holding portion 40, the second holding portion 44, and the third holding portion 48 via the rail members 52 respectively, the first electronic component 18, the second electronic component 20, and the third electronic component 22 can be inserted into the circuit board 72, so as to establish electrical connection between the first electronic component 18, the second electronic component 20, the third electronic component 22, and the main body 14. Furthermore, the present disclosure could adopt a removable front cover design (but not limited thereto, meaning that the present disclosure could adopt a fixed front cover design in another embodiment). For example, as shown in FIG. 1, the first electronic component 18 could have a front cover 78. The front cover 78 could be detachably locked to the containing casing 24 (e.g., by using a screw 79 as shown in FIG. 1, but not limited thereto) when the first electronic component 18 is mounted on the first holding portion 40, so as to allow the user to quickly and easily complete the disassembling and replacing operation of the electronic components.

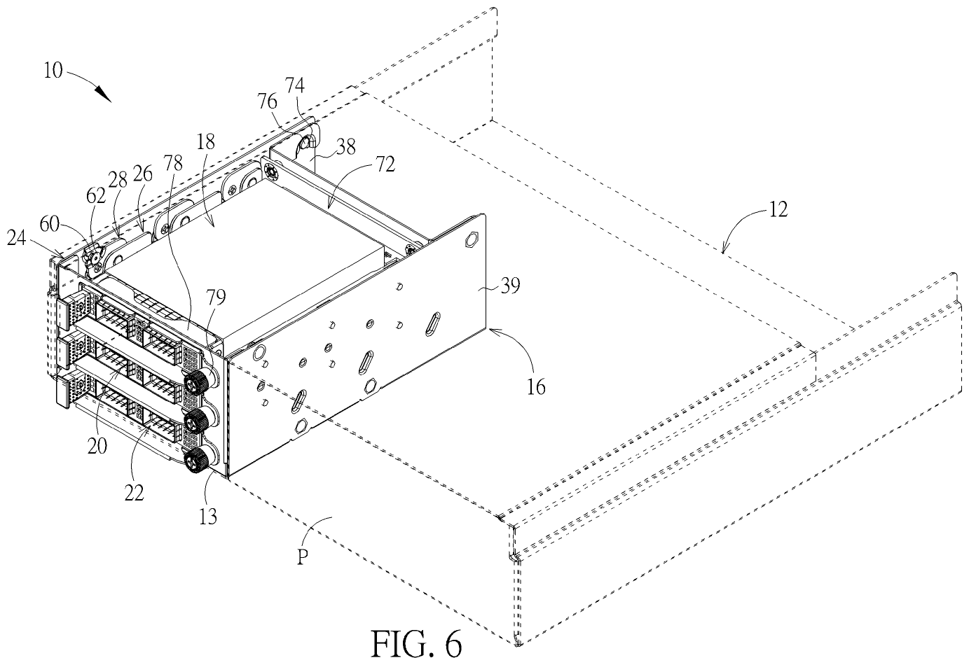

Detailed description for the electronic component assembling operation of the containing mechanism 16 is provided as follows. Please refer to FIGS. 1-6. FIG. 6 is an assembly diagram of the containing casing 24 with the first electronic component 18, the second electronic component 20, and the third electronic component 22 being disposed through the opening 13 of the server casing 12. For clearly showing the assembly configuration of the containing mechanism 16, the server casing 12 is shown in dashed lines in FIG. 6. When the user wants to perform the electronic component assembly operation of the server apparatus 10, the user just needs to dispose the first support member 26, the second support member 30, and the third support member 34 linked to each other by the linkage member 28, the first bridge member 32, and the second bridge member 36 in the containing casing 24. In brief, as mentioned above, the user can sequentially fix the rail members 52 to the third support member 34, the second support member 30, and the first support member 26 moving to the offset position as shown in FIG. 1, and then move the first support member 26, the second support member 30, and the third support member 34 to the stacking position as shown in FIG. 5 to make the linkage member 28 detachably fixed to the second fixing part 62 via the first fixing part 60. After the circuit board 72 is disposed upright in the containing casing 24, the containing mechanism 16 as shown in FIG. 5 can be disposed through the opening 13 of the server casing 12 and the first electronic component 18, the second electronic component 20, and the third electronic component 22 can be mounted on the first holding portion 40, the second holding portion 44, and the third holding portion 48 via the rail members 52 respectively and connected to the main body 14 via the circuit board 72, so as to make the first electronic component 18, the second electronic component 20, and the third electronic component 22 disposed in the containing casing 24 (e.g., in a stacking manner as shown in FIG. 6, but not limited thereto) for completing the assembly operation of the server apparatus 10.

In summary, via the aforesaid design of mounting the first support member 26, the second support member 30, and the third support member 34 in the containing casing 24, wherein the first support member 26, the second support member 30, and the third support member 34 are linked to each other via the linkage member 28, the first bridge member 32, and the second bridge member 36, the present disclosure can utilize the first support member 26, the second support member 30, and the third support member 34 to support the first electronic component 18, the second electronic component 20, and the third electronic component 22 in the containing casing 24 (as shown in FIG. 6). As such, other server components (e.g., input/output ports) can be additionally mounted in the remaining space other than the opening 13 at the front end P of the server casing 12 of the server apparatus 10. In such a manner, the present disclosure can effectively solve the prior art problem that the expansion electronic components horizontally adjacent to each other may fully occupy the horizontal configuration space of the server casing and prevent the possibility of adding extra input-output (I/O) ports on the server. Thus, the present disclosure can greatly improve the configuration flexibility and expansion functionality of the server apparatus in mounting server components.

It should be mentioned that the number of stacked electronic components in the server apparatus of the present disclosure is not limited to the aforesaid embodiments. The present disclosure could also adopt a stacking design with only two layers or more than three layers. For example, in another embodiment where the third support member is omitted, the present disclosure could only utilize the first support member 26 and the second support member 30 linked to each other by the linkage member 28 and the first bridge member 32, to mount the first electronic component 18 and the second electronic component 20 in the containing casing 24 to achieve a double-layer stacking configuration. The aforesaid positioning groove design could be selectively applied to the second support member 30 to assist the user in quickly and accurately completing the assembly operation of mounting the first support member 26 and the second support member 30 in the containing casing 24, and the related description could be reasoned by analogy according to the aforesaid embodiments and omitted herein. As for the related description for other derived embodiments with different numbers of stacked electronic components (e.g., a multi-layer (four layers or more) configuration of adding support members to be linked under the third support member), it could be reasoned by analogy according to the aforesaid embodiments and omitted herein.

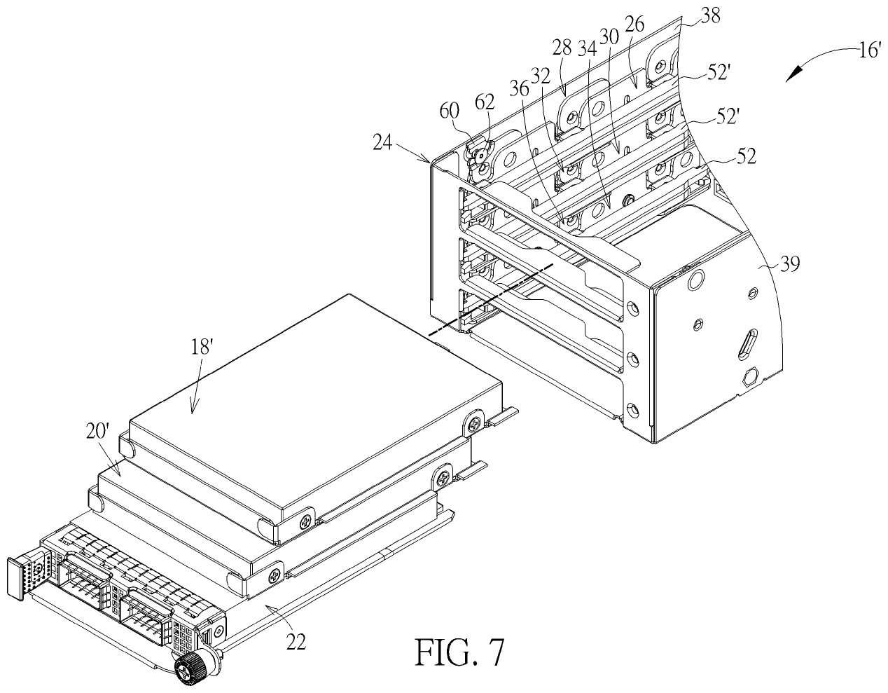

In addition, the types of electronic components that the containing mechanism can support are not limited to the aforesaid embodiments. In other words, the containing mechanism provided by the present disclosure can be suitable for any electronic component that can be mounted on the aforesaid support members (e.g., in a screw-locking manner or by the aforesaid rail members, but not limited thereto). In another embodiment, a first electronic component 18′ and a second electronic component 20′ could be 2.5-inch hard disk devices and the third electronic component 22 could be a network card complying with the OCP 3.0 specification (but not limited thereto). Please refer to FIG. 7, which is an assembly diagram of the first electronic component 18′, the second electronic component 20′, the third electronic component 22 and a containing mechanism 16′ according to another embodiment of the present disclosure. Components both mentioned in this embodiment and the aforesaid embodiments represent components with similar structures or functions, and the related description could be reasoned by analogy according to the aforesaid embodiments and omitted herein. As shown in FIG. 7, the containing mechanism 16′ could include the containing casing 24, the first support member 26, the second support member 30, the first bridge member 32, the third support member 34, the second bridge member 36, the rail member 52 and two rail members 52′. The rail design of the rail member 52′ could meet the size specification of a side piece of a 2.5-inch hard drive device, allowing the 2.5-inch hard drive device to be slidably inserted thereto. In such a manner, after the rail member 52 and the two rail members 52′ are sequentially fixed to the third support member 34, the second support member 30, and the first support member 26 moving to the offset position, the first support member 26 and the third support member 34 moves to the stacking position relative to the second support member 30 respectively, and the first fixing part 60 of the first support member 26 is detachably fixed to the second fixing part 62 of the first side plate 38, the containing mechanism 16′ can be disposed through the opening 13 of the server casing 12, and the first electronic component 18′, the second electronic component 20′, and the third electronic component 22 can be mounted on the first support member 26, the second support member 30 and the third support member 34 via the rail member 52 and the two rail member 52′ respectively and connected to the main body 14. As such, the first electronic component 18′, the second electronic component 20′, and the third electronic component 22 can be mounted in the containing casing 24 preferably in a stacking manner (but not limited thereto) for completing the assembly operation of the containing mechanism 16′.

In summary, the present disclosure can utilize the first support member, the second support member, and the third support member to support different types of electronic components. Thus, the present disclosure can effectively solve the prior art problem that different types of expansion electronic components have different mounting sizes and cannot be mixedly stacked on the tray mechanism, so as to greatly improve the configuration flexibility and expansion functionality of the server apparatus in mounting server components.

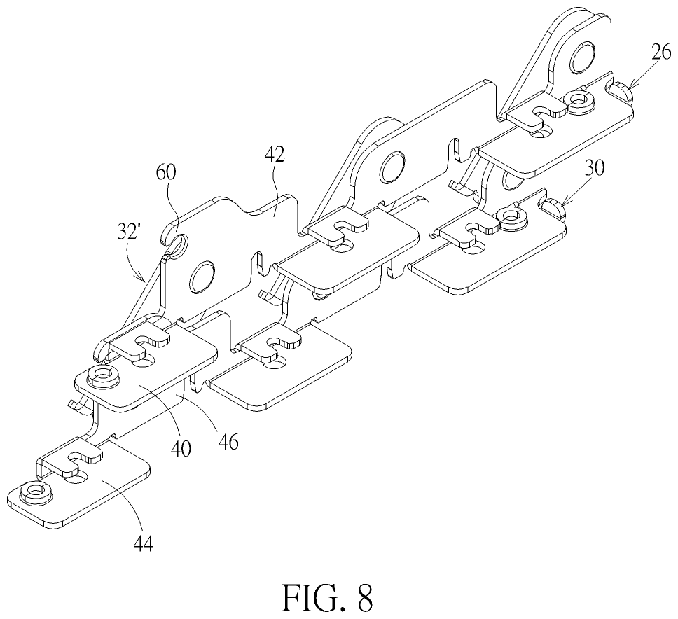

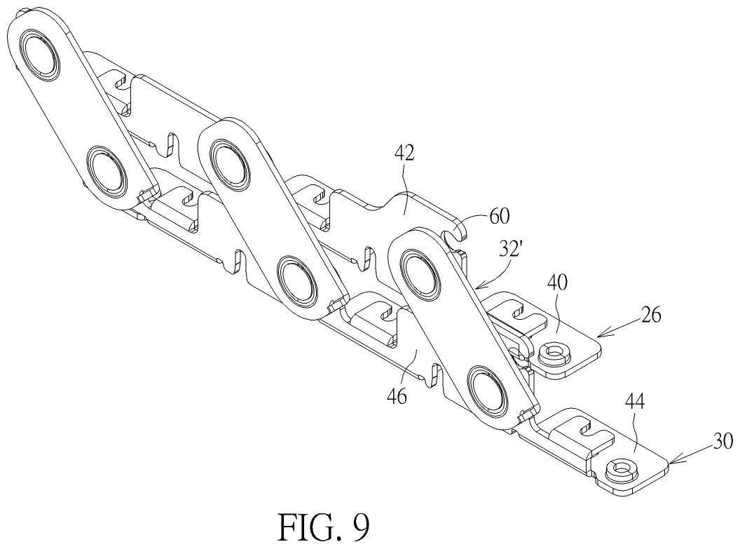

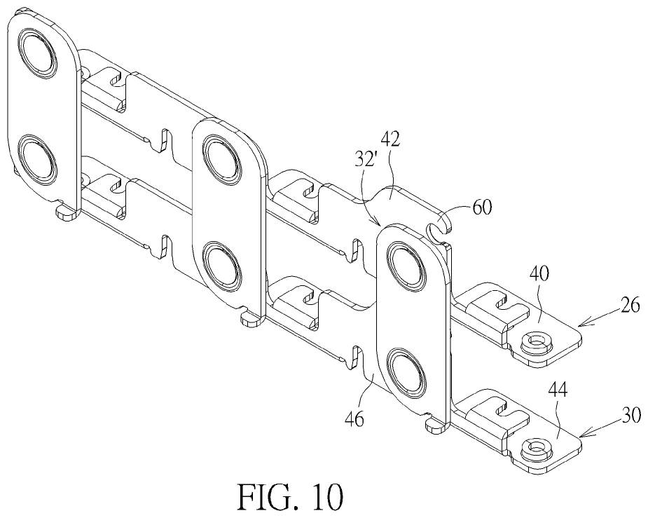

In practical applications, the linkage member could be an omissible component for further simplifying the linkage design of the containing mechanism. For example, please refer to FIGS. 8, 9, and 10. FIG. 8 is an enlarged diagram of the first support member 26 being connected to the second support member 30 via a first bridge member 32′ according to another embodiment of the present disclosure. FIG. 9 is an enlarged diagram of the first support member 26, the second support member 30, and the first bridge member 32′ in FIG. 8 from another viewing angle. FIG. 10 is an enlarged diagram of the first support member 26 in FIG. 9 being aligned with the second support member 30 via the first bridge member 32′. Components both mentioned in this embodiment and the aforesaid embodiments represent components with similar structures or functions, and the related description could be reasoned by analogy according to the aforesaid embodiments and omitted herein. In brief, in this embodiment, the containing mechanism of the present disclosure could include the containing casing 24, the first support member 26, the second support member 30, at least one first bridge member 32′ (three shown in FIG. 9, but not limited thereto, meaning that the actual number depends on the actual support requirements of the containing mechanism), the third support member 34, and the second bridge member 36. The first support member 26 has the first fixing part 60 (e.g., formed integrally on the first connection portion 42 as shown in FIG. 8), and the first bridge member 32′ is pivotally connected to the first connection portion 42 of the first support member 26 and the second connection portion 46 of the second support member 30. In such a manner, via pivoting of the first bridge member 32′ relative to the first connection portion 42 and the second connection portion 46, the first support member 26 can be offset relative to the second support member 30 (as shown in FIG. 9) or aligned with the second support member 30 (as shown in FIG. 10) for the subsequent electronic component mounting process.

Those skilled in the art will readily observe that numerous modifications and alterations of the device and method could be made while retaining the teachings of the invention. Accordingly, the above disclosure should be construed as limited only by the metes and bounds of the appended claims.

What is claimed is:

1. A server apparatus comprising:
a server casing;
a main body disposed in the server casing;
a containing mechanism comprising:
a containing casing located in the server casing and having a first side plate;
a first support member of the first side plate having a first fixing part, a first holding portion, and a first connection portion extending from the first holding portion, the first fixing part being disposed on the first connection portion;
a second support member of the first side plate having a second holding portion and a second connection portion extending from the second holding portion; and
a first bridge member of the first side plate pivoted to the first connection portion and the second connection portion respectively, the first support member being movable relative to the second support member via the first bridge member via the first bridge member being pivoted to the first connection portion and the second connection portion;
a first electronic component located on the first holding portion and connected to the main body; and
a second electronic component located on the second holding portion and connected to the main body;
wherein the first fixing part is detachably fixed to the first side plate.

2. The server apparatus of claim 1, wherein the first support member further comprises a linkage member, the first fixing part is disposed on the linkage member, the linkage member is pivoted to the first connection portion, the first bridge member is connected to the linkage member, the first support member being movable to a stacking position relative to the second support member via pivoting of the linkage member and the first bridge member, the first side plate has a second fixing part, and the first fixing part is fixed to the second fixing part when the first support member is at the stacking position.

3. The server apparatus of claim 2, wherein the first fixing part is an engaging hook, the second fixing part is a spring-loaded plunger, the engaging hook is engaged with the spring-loaded plunger securely, when the engaging hook is engaged with the spring-loaded plunger, the linkage member is fixed to the first side plate, and the engaging hook is pivotable relative to the first connection portion to be disengaged from the spring-loaded plunger when the spring-loaded plunger is pressed.

4. The server apparatus of claim 1, wherein the second connection portion forms a positioning groove, the first side plate has a positioning pin corresponding to the positioning groove, and when the positioning groove is engaged with the positioning pin the second support member is positioned on the first side plate.

5. The server apparatus of claim 1, wherein the containing mechanism further includes a rail member, the first electronic component has a side piece, a clamping piece is formed when the first connection portion is bent toward the first holding portion, the rail member has a protrusion corresponding to the clamping piece, the rail member is fixed to the first holding portion when the protrusion is clamped between the clamping piece and the first holding portion, and the first electronic component is mounted on the first holding portion via the side piece being slidably disposed through the rail member.

6. The server apparatus of claim 1, wherein the containing mechanism further includes a circuit board disposed upright in the containing casing and electrically connected to the main body, and the first electronic component and the second electronic component are electrically connected to the main body via inserting the first electronic component and the second electronic component into the circuit board.

7. The server apparatus of claim 1, wherein the first electronic component has a front cover, and the front cover is detachably locked to the containing casing when the first electronic component is mounted on the first holding portion.

8. The server apparatus of claim 2, wherein the server apparatus further comprises a third electronic component, the containing mechanism further comprises a third support member and a second bridge member, the third support member has a third holding portion and a third connection portion extending from the third holding portion, the second bridge member is pivoted to the third connection portion and connected to the first bridge member, the third support member being movable relative to the second support member via pivoting of the first bridge member relative to the second connection portion and pivoting of the second bridge member relative to the third connection portion, and the third electronic component is mounted on the third holding portion and is connected to the main body, wherein the linkage member is detachably fixed to the first side plate, the first electronic component, the second electronic component and the third electronic component disposed in the containing casing in a stacking manner when the linkage member is fixed to the first side plate.

9. The server apparatus of claim 8, wherein a positioning groove is formed at the third connection portion, the first side plate has a positioning pin corresponding to the positioning groove, the positioning groove is engaged with the positioning pin, and the third support member is positioned on the first side plate when the positioning groove is engaged with the positioning pin.

10. The server apparatus of claim 1, wherein the containing casing further has a second side plate opposite to the first side plate, and the containing mechanism further comprises:
a first support member of the second side plate having a first fixing part, a first holding portion, and a first connection portion extending from the first holding portion, the first fixing part being disposed on the first connection portion;
a second support member of the second side plate having a second holding portion and a second connection portion extending from the second holding portion; and
a first bridge member of the second side plate pivoted to the first connection portion and the second connection portion respectively, the first support member being movable relative to the second support member via the first bridge member;
wherein the first fixing part is detachably fixed to the second side plate, the first electronic component and the second electronic component are disposed in the containing casing in a stacking manner when the first fixing part is fixed to the second side plate.

11. A containing mechanism suitable for a server casing, the containing mechanism comprising:
a containing casing located in the server casing and having a first side plate;
a first support member of the first side plate having a first fixing part, a first holding portion, and a first connection portion extending from the first holding portion, the first fixing part being disposed on the first connection portion;
a second support member of the first side plate having a second holding portion and a second connection portion extending from the second holding portion; and
a first bridge member of the first side plate pivoted to the first connection portion and the second connection portion respectively, the first support member movable relative to the second support member via the first bridge member being pivoted to the first connection portion and the second connection portion;
wherein a first electronic component and a second electronic component are located on the first holding portion and the second holding portion respectively, and the first fixing part is detachably fixed to the first side plate.

12. The containing mechanism of claim 11, wherein the first support member further comprises a linkage member, the first fixing part is disposed on the linkage member, the linkage member is pivoted to the first connection portion, the first bridge member is connected to the linkage member, the first support member being movable to a stacking position relative to the second support member via pivoting of the linkage member and the first bridge member, the first side plate has a second fixing part, and the first fixing part is fixed to the second fixing part when the first support member is at the stacking position.

13. The containing mechanism of claim 12, wherein the first fixing part is an engaging hook, the second fixing part is a spring-loaded plunger, the engaging hook is engaged with the spring-loaded plunger securely, when the engaging hook is engaged with the spring-loaded plunger securely the linkage member is fixed to the first side plate, and the engaging hook is pivotable relative to the first connection portion to be disengaged from the spring-loaded plunger when the spring-loaded plunger is pressed.

14. The containing mechanism of claim 11, wherein the second connection portion forms a positioning groove, the first side plate has a positioning pin corresponding to the positioning groove, and when the positioning groove is engaged with the positioning pin the second support member is positioned on the first side plate.

15. The containing mechanism of claim 11, wherein the containing mechanism further includes a rail member, the first electronic component has a side piece, a clamping piece is formed when the first connection portion is bent toward the first holding portion, the rail member has a protrusion corresponding to the clamping piece, the rail member is fixed to the first holding when the protrusion is clamped between the clamping piece and the first holding portion, and the first electronic component is mounted on the first holding portion via the side piece being slidably disposed through the rail member.

16. The containing mechanism of claim 11, wherein the containing mechanism further includes a circuit board disposed upright in the containing casing, and the first electronic component and the second electronic component are electrically connected to the main body via inserting the first electronic component and the second electronic component into the circuit board.

17. The containing mechanism of claim 11, wherein the first electronic component has a front cover, and the front cover is detachably locked to the containing casing when the first electronic component is mounted on the first holding portion.

18. The containing mechanism of claim 12, wherein the containing mechanism further comprises a third support member and a second bridge member, the third support member has a third holding portion and a third connection portion extending from the third holding portion, the second bridge member is pivoted to the third connection portion and connected to the first bridge member, the third support member being movable relative to the second support member via pivoting of the first bridge member relative to the second connection portion and pivoting of the second bridge member relative to the third connection portion, and a third electronic component is mounted on the third holding portion, wherein the linkage member is detachably fixed to the first side plate, the first electronic component, the second electronic component and the third electronic component disposed in the containing casing in a stacking manner when the linkage member is fixed to the first side plate.

19. The containing mechanism of claim 18, wherein a positioning groove is formed at the third connection portion, the first side plate has a positioning pin corresponding to the positioning groove, the positioning groove is engaged with the positioning pin, and the third support member is positioned on the first side plate when the positioning groove is engaged with the positioning pin.

20. The containing mechanism of claim 11, wherein the containing casing further has a second side plate opposite to the first side plate, and the containing mechanism further comprises:
a first support member of the second side plate having a first fixing part, a first holding portion, and a first connection portion extending from the first holding portion, the first fixing part being disposed on the first connection portion;
a second support member of the second side plate having a second holding portion and a second connection portion extending from the second holding portion; and
a first bridge member of the second side plate pivoted to the first connection portion and the second connection portion respectively, the first support member being movable relative to the second support member via the first bridge member;
wherein the first fixing part is detachably fixed to the second side plate, the first electronic component and the second electronic component disposed in the containing casing in a stacking manner when the first fixing part is fixed to the second side plate.
